(19) United States
(12) Patent Application Publication
(10) Pub. No.: US 2026/0071323 A1
(43) Pub. Date: Mar. 12, 2026

(54) ATOMIC LAYER DEPOSITION APPARATUS

(71) Applicant: Samsung Display Co., Ltd., Yongin-si (KR)

(72) Inventors: CHOELMIN JANG, Yongin-si (KR); JUNGGON KIM, Yongin-si (KR); MIN-GYU PARK, Yongin-si (KR)

(21) Appl. No.: 19/244,528

(22) Filed: Jun. 20, 2025

(30) Foreign Application Priority Data
Sep. 6, 2024 (KR) 10-2024-0121366

(51) Int. Cl. C23C 16/44; C23C 16/455

(52) U.S. Cl. CPC C23C 16/4412; C23C 16/45544

(57) ABSTRACT

An atomic layer deposition apparatus includes a source gas supply part for supplying a plurality of source gases, a source gas supply module connected to the source gas supply part, an exhaust part connected to and disposed above the source gas supply module, and an exhaust plasma supply part connected to the exhaust part and for applying an exhaust plasma to the exhaust part. The exhaust part applies the exhaust plasma received from the exhaust plasma supply part to the source gas supply module, sucks the exhaust plasma applied to the source gas supply module, and exhausts the sucked plasma to the outside.

This application claims priority to Korean Patent Application No. 10-2024-0121366, filed on Sep. 6, 2024, and all the benefits accruing therefrom under 35 U.S.C. § 119, the content of which in its entirety is herein incorporated by reference.

### BACKGROUND

### 1. Field

The present disclosure relates to an atomic layer deposition apparatus.

### 2. Description of Related Art

In general, methods such as physical vapor deposition (PVD) and chemical vapor deposition (CVD) are used to deposit thin layers on a substrate. However, as the size of semiconductor devices becomes smaller, there is an increasing demand for thin layers with fine patterns, and the use of atomic layer deposition (ALD) method, which is able to deposit even finer thin layers, has been growing.

The atomic layer deposition (ALD) method is defined as a process where thin layers are formed by stacking atomic layers one by one. The atomic layer deposition (ALD) method is divided into three stages, adsorption, substitution, and production.

In the adsorption stage, a precursor in a gaseous state is injected into a process chamber and adsorbed onto a surface of a substrate. In the substitution stage, a reactant in a gaseous state is injected into the process chamber and provided onto the substrate, and a chemical substitution reaction occurs between the precursor adsorbed onto the substrate and the reactant. In the production stage, a layer of material different from the precursor and the reactant is formed based on the chemical substitution reaction. The formed layer is adsorbed onto the surface of the substrate as a single atomic layer. Through this process, a single layer is deposited and formed on the substrate.

By repeating the above process, the required thickness of the thin layer is achieved, and residual gases are exhausted through an exhaust pipe. As the residual gases are vented through the exhaust pipe, they form a layer on the wall of the exhaust pipe. The layer accumulated on the wall of the exhaust pipe blocks the exhaust pipe or falls down to the substrate as particles.

The layer formed on the inner wall of the exhaust pipe is removed by cleaning radicals injected into the exhaust pipe. The layer formed on the inner wall of the exhaust pipe reacts with the cleaning radicals injected into the exhaust pipe. However, the longer and more complex the exhaust pipe, the more likely it is that the cleaning radicals are recombined with each other without reacting with the layer formed on the inner wall of the exhaust pipe. Accordingly, as the layer formed on the inner wall of the exhaust pipe is farther from a nozzle injecting the cleaning radicals, the cleaning efficiency becomes lower.

### SUMMARY

The present disclosure provides an atomic layer deposition apparatus capable of easily cleaning an exhaust part.

Embodiments of the invention provide an atomic layer deposition apparatus including a source gas supply part for supplying a plurality of source gases, a source gas supply module connected to the source gas supply part, an exhaust part connected to and disposed above the source gas supply module, and an exhaust plasma supply part connected to the exhaust part and for applying an exhaust plasma to the exhaust part. The exhaust part applies the exhaust plasma received from the exhaust plasma supply part to the source gas supply module, sucks the exhaust plasma applied to the source gas supply module, and exhausts the sucked plasma to the outside.

The source gas supply module may include a first source gas supply module for supplying a first source gas to a substrate and a second source gas supply module for supplying a second source gas to the substrate, where the plurality of source gases includes the first source gas and the second source gas.

The first source gas supply module may include a plurality of first source gas nozzles connected to the source gas supply part, and the second source gas supply module may include a plurality of second source gas nozzles connected to the source gas supply part.

The first and second source gas nozzles may be alternately arranged in the order of the first source gas nozzle and the second source gas nozzle.

The atomic layer deposition apparatus may further include a plurality of barrier walls disposed between the first and second source gas nozzles.

The exhaust part may include an exhaust pump, a first exhaust pipe connected to the first source gas supply module, and a second exhaust pipe connected to the second source gas supply module.

The atomic layer deposition apparatus may further include an exhaust plasma pipe connected to the first and second exhaust pipes, and the exhaust plasma supply part may apply the exhaust plasma to the exhaust plasma pipe.

The atomic layer deposition apparatus may further include a first valve for connecting the first exhaust pipe and the exhaust pump and controlling an exhaust of the exhaust plasma sucked from the first source gas supply module to the outside, and a second valve for connecting the second exhaust pipe and the exhaust pump and controlling the exhaust of the exhaust plasma sucked from the second source gas supply module to the outside.

The atomic layer deposition apparatus may further include a third valve for connecting the first exhaust pipe and the exhaust plasma pipe and controlling an application of the exhaust plasma to the first exhaust pipe and a fourth valve for connecting the second exhaust pipe and the exhaust plasma pipe and controlling the application of the exhaust plasma to the second exhaust pipe.

The first exhaust pipe may receive the exhaust plasma from the exhaust plasma supply part and apply the exhaust plasma to the first source gas supply module, and the exhaust plasma applied to the first source gas supply module may be exhausted to the second exhaust pipe through the second source gas supply module.

When the third valve is opened, the exhaust plasma may be applied from the exhaust plasma supply part to the first exhaust pipe and the fourth valve may be closed, and when the second valve is opened, the exhaust plasma may be exhausted to the second exhaust pipe and the first valve may be closed.

The second exhaust pipe may receive the exhaust plasma from the exhaust plasma supply part and apply the exhaust plasma to the second source gas supply module, and the exhaust plasma applied to the second source gas supply module may be exhausted to the first exhaust pipe through the first source gas supply module.

When the fourth valve is opened, the exhaust plasma may be applied from the exhaust plasma supply part to the second exhaust pipe and the third valve may be closed, and when the first valve is opened, the exhaust plasma sucked from the first source gas supply module may be exhausted to the first exhaust pipe and the second valve may be closed.

The atomic layer deposition apparatus may further include a pipe connected to the first and second source gas supply modules, a pump connected to the pipe, and a fifth valve for connecting the pipe and the pump and controlling the exhaust of the exhaust plasma to the pump.

The first exhaust pipe may receive the exhaust plasma and apply the exhaust plasma to the first source gas supply module, the second exhaust pipe may receive the exhaust plasma and apply the exhaust plasma to the second source gas supply module, and the exhaust plasma applied to the first and second source gas supply modules may be exhausted through the pipe.

When the third and fourth valves are opened, the exhaust plasma may be applied to the first and second exhaust pipes and the first and second valves may be closed, and when the fifth valve is opened, the exhaust plasma may be exhaust to the pump.

Embodiments of the invention provide an atomic layer deposition apparatus including a source gas supply part for supplying a plurality of source gases including a first source gas and a second source gas, a first source gas supply module connected to the source gas supply part and for supplying the first source gas, a second source gas supply module connected to the source gas supply part and for supplying the second source gas, a purge gas supply module disposed between the first source gas supply module and the second source gas supply module, a purge gas supply part for supplying a purge gas to the purge gas supply module, an exhaust part connected to the first and second source gas supply modules and disposed above the first and second source gas supply modules and the purge gas supply module, and an exhaust plasma supply part connected to the exhaust part and for applying an exhaust plasma to the exhaust part. The exhaust part applies the exhaust plasma received from the exhaust plasma supply part to the first and second source gas supply modules, and the first and second source gas supply modules exhaust the exhaust plasma applied thereto to the exhaust part.

The purge gas supply module may have a slit shape.

The first source gas supply module may include a first source gas nozzle connected to the source gas supply part, the second source gas supply module may include a second source gas nozzle connected to the source gas supply part, and the purge gas supply module may include a purge gas nozzle connected to the purge gas supply part.

The first and second source gas nozzles and the purge gas nozzle may be repeatedly arranged in the order of the first source gas nozzle, the second source gas nozzle, and the purge gas nozzle.

According to the atomic layer deposition apparatus, the plasma is directly applied to the exhaust pipe, and thus, a layer of deposits accumulated on an inner wall of the exhaust pipe is cleaned more efficiently.

### BRIEF DESCRIPTION OF THE DRAWINGS

The above and other advantages of the present disclosure will become readily apparent by reference to the following detailed description when considered in conjunction with the accompanying drawings wherein:

FIG. 1 is a perspective view of an atomic layer deposition apparatus according to an embodiment of the present disclosure;

FIGS. 2A to 2C are views illustrating an atomic layer deposition method according to an embodiment of the present disclosure;

FIG. 3 is a cross-sectional view of a pixel including a thin layer formed by the atomic layer deposition apparatus shown in FIG. 1;

FIG. 4 is a cross-sectional view taken along line I-I′ shown in FIG. 1;

FIG. 5 is a cross-sectional view taken along line II-II′ shown in FIG. 1;

FIG. 6A is a view illustrating a process of supplying a first source gas to a substrate;

FIG. 6B is a view illustrating a process of supplying a second source gas to a substrate;

FIGS. 7A and 7B are views illustrating an operation of an exhaust plasma supply part after an atomic layer is formed on a substrate according to an embodiment of the present disclosure;

FIG. 8 is a view illustrating an operation of an exhaust plasma supply part after an atomic layer is formed on a substrate according to an embodiment of the present disclosure;

FIG. 9A is a cross-sectional view of a deposition module according to an embodiment of the present disclosure; and

FIG. 9B is a cross-sectional view of an atomic layer deposition apparatus according to an embodiment of the present disclosure.

### DETAILED DESCRIPTION

In the present disclosure, it will be understood that when an element (or area, layer, or portion) is referred to as being “on”, “connected to” or “coupled to” another element or layer, it can be directly on, connected or coupled to the other element or layer or intervening elements or layers may be present.

Like numerals refer to like elements throughout. In the drawings, the thickness, ratio, and dimension of components are exaggerated for effective description of the technical content.

As used herein, the term “and/or” may include any and all combinations of one or more of the associated listed items.

It will be understood that, although the terms “first”, “second”, etc. may be used herein to describe various elements, these elements should not be limited by these terms. These terms are only used to distinguish one element from another element. Thus, a first element discussed below could be termed a second element without departing from the teachings of the present disclosure. As used herein, the singular forms, “a”, “an” and “the” are intended to include the plural forms as well, unless the context clearly indicates otherwise.

Spatially relative terms, such as “beneath”, “below”, “lower”, “above”, “upper” and the like, may be used herein for ease of description to describe one element or feature's relationship to another elements or features as shown in the figures.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

Hereinafter, embodiments of the present disclosure will be described with reference to accompanying drawings.

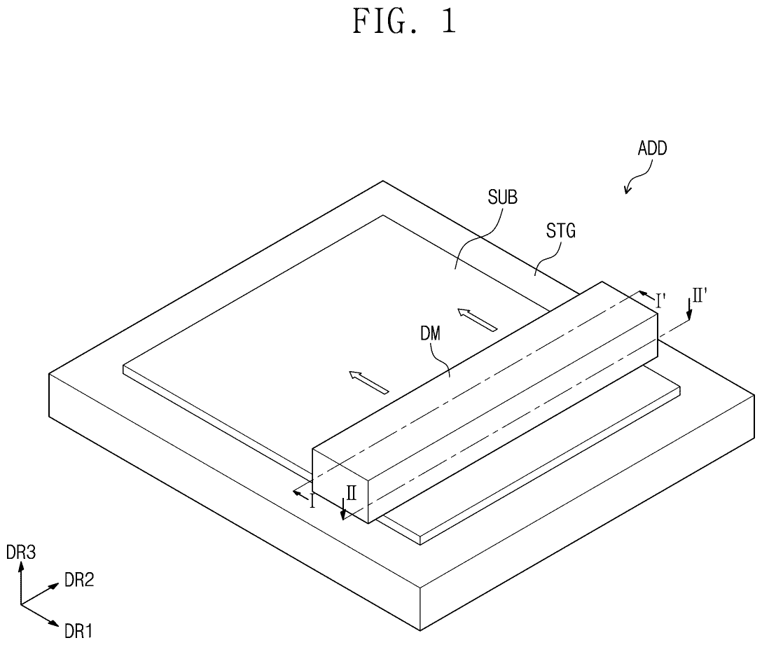

FIG. 1 is a perspective view of an atomic layer deposition apparatus ADD according to an embodiment of the present disclosure.

Referring to FIG. 1, the atomic layer deposition apparatus ADD may include a stage STG and a deposition module DM disposed on the stage STG. The stage STG may have a rectangular shape defined by long sides extending in a first direction DR1 and short sides extending in a second direction DR2 intersecting the first direction DR1.

Hereinafter, a direction substantially perpendicular to a plane defined by the first direction DR1 and the second direction DR2 may be referred to as a third direction DR3. In the present disclosure, the expression “when viewed in a plane” may mean a state of being viewed in the third direction DR3.

A substrate SUB may be disposed on an upper surface of the stage STG. The substrate SUB may have a rectangular shape defined by long sides extending in the first direction DR1 and short sides extending in the second direction DR2 intersecting the first direction DR1.

The deposition module DM may be disposed on the substrate SUB. The deposition module DM may move back and forth in the first direction DR1 and a direction opposite to the first direction DR1 on the substrate SUB, however, the present disclosure should not be limited thereto or thereby. According to an embodiment, the deposition module DM may be fixed at a certain position, and then the substrate SUB may move back and forth in the first direction DR1 and the direction opposite to the first direction DR1. In this case, the stage STG may be implemented as a movable stage to move the substrate SUB.

The deposition module DM may have a rectangular shape defined by short sides extending in the first direction DR1 and long sides extending in the second direction DR2 intersecting the first direction DR1. That is, the deposition module DM may further extend in the second direction DR2 than in the first direction DR1.

The deposition module DM may be a deposition head. The deposition module DM may spray a deposition material onto the substrate SUB to form a thin layer on the substrate SUB. The deposition material may be deposited in the unit of atomic layer. The structure and operation of the deposition module DM will be described in detail later.

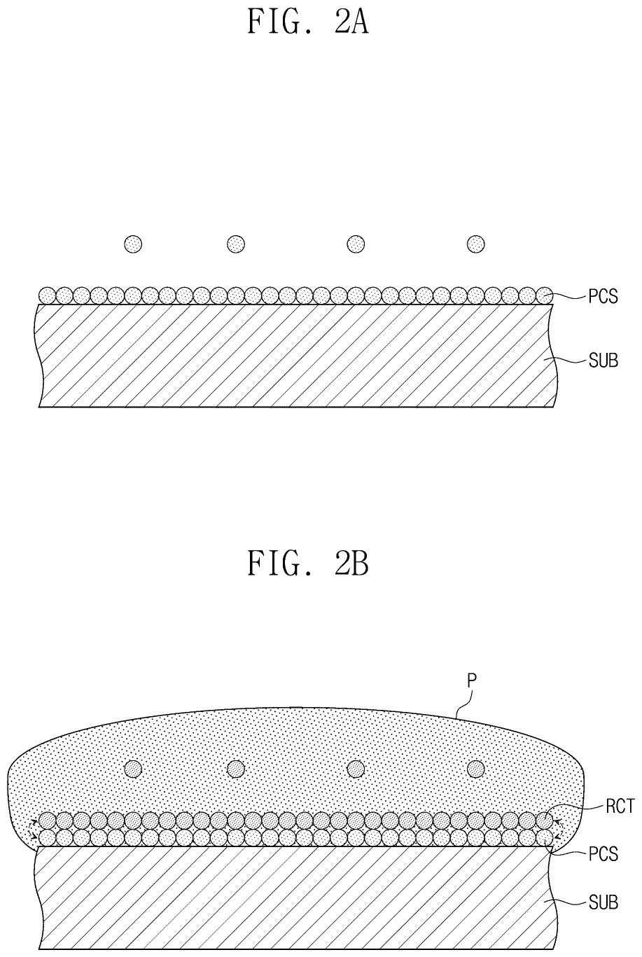

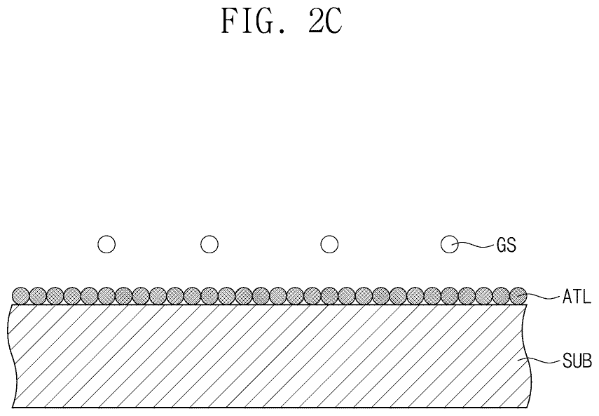

FIGS. 2A to 2C are views illustrating an atomic layer deposition method according to an embodiment of the present disclosure.

As an example, FIGS. 2A to 2C illustrate a process of forming a silicon oxide layer using a plasma atomic layer deposition method.

Referring to FIG. 2A, a precursor PCS in gaseous form may be sprayed on the substrate SUB. The precursor PCS may be referred to as a first source gas. As an example, the precursor PCS may include silane (SiH₄). The precursor PCS may be adsorbed onto the substrate SUB. As an example, a silane molecule (SiH₄) may be adsorbed onto the substrate SUB.

The precursor PCS may be adsorbed onto the substrate SUB only as a single layer. Even if silane (SiH₄) is continuously supplied as the precursor PCS, only one layer may be formed on the substrate SUB. This may be defined as a self-limiting reaction. The precursor PCS remaining without being adsorbed onto the substrate SUB may be exhausted to the outside.

Referring to FIG. 2B, a reactant RCT in gaseous form may be sprayed onto the substrate SUB. The reactant RCT may be referred to a second source gas. As an example, the reactant RCT may be O₂ or N₂O. The oxygen molecules of O₂ or N₂O may be supplied onto the substrate SUB. The reactant RCT may be decomposed by a plasma P and may be supplied as radicals onto the substrate SUB.

The reactant RCT may react with the precursor PCS through the chemical substitution reaction. As an example, O₂ or N₂O may react with SiH₄ through the chemical substitution reaction. As with the precursor PCS, only one layer may undergo adsorption or substitution reaction even if the reactant RCT, e.g., O₂ or N₂O, is continuously supplied. The remaining reactant RCT may be exhausted to the outside.

Referring to FIG. 2C, one atomic layer ATL may be formed on the substrate SUB according to the chemical substitution reaction between the reactant RCT and the precursor PCS. As an example, when the reactant RCT is O₂, O₂ may react with SiH₄ through the chemical substitution reaction, only SiO₂ may be formed on the substrate SUB as a single layer, and a gas GS, e.g., H₂O, remaining after the substitution reaction may be exhausted to the outside.

In addition, when the reactant RCT is N₂O, N₂O may react with SiH₄ through the chemical substitution reaction, only SiO₂ may be formed on the substrate SUB as a single layer, and a gas GS, e.g., N₂ or H₂, remaining after the substitution reaction may be exhausted to the outside.

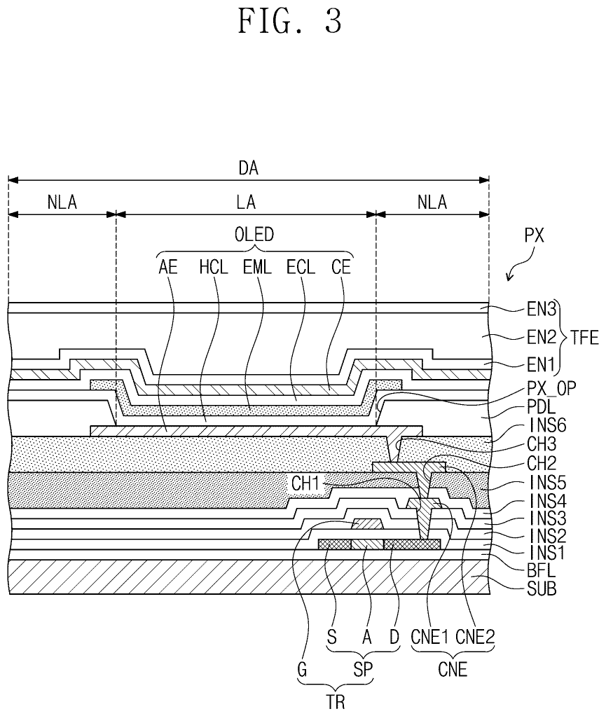

FIG. 3 is a cross-sectional view of a pixel PX including a thin layer formed by the atomic layer deposition apparatus shown in FIG. 1.

Referring to FIG. 3, the pixel PX may include a transistor TR and a light emitting element OLED. The light emitting element OLED may include a first electrode (or an anode) AE, a second electrode (or a cathode) CE, a hole control layer HCL, an electron control layer ECL, and a light emitting layer EML.

The transistor TR and the light emitting element OLED may be disposed on the substrate SUB. As an example, one transistor TR is shown in FIG. 3, however, the pixel PX may include a plurality of transistors and at least one capacitor to drive the light emitting element OLED.

A display area DA may include a light emitting area LA corresponding to each pixel PX and a non-light-emitting area NLA around the light emitting area LA. The light emitting element OLED may be disposed in the light emitting area LA.

The substrate SUB may include a flexible plastic material, e.g., polyimide (PI). A buffer layer BFL may be disposed on the substrate SUB, and the buffer layer BFL may be an inorganic layer.

A semiconductor pattern SP may be disposed on the buffer layer BFL. The semiconductor pattern SP may be formed by the atomic layer deposition apparatus ADD shown in FIG. 1. The semiconductor pattern SP may include an oxide semiconductor. As an example, the oxide semiconductor may include a transparent conductive oxide (TCO), such as indium tin oxide (ITO), indium zinc oxide (IZO), indium gallium zinc oxide (IGZO), zinc oxide (ZnO), or indium oxide (In₂O₃).

The semiconductor pattern SP may include a plurality of areas distinguished from each other depending on whether a metal oxide is reduced or not. The area (hereinafter, referred to as a reduced area) in which the metal oxide is reduced has a conductivity greater than that of the area (hereinafter, referred to as a non-reduced area) in which the metal oxide is not reduced. The reduced area may substantially act as a source electrode or a drain electrode of a transistor. The non-reduced area may substantially correspond to an active (or a channel) of the transistor.

A source S, an active A, and a drain D of the transistor TR may be formed from the semiconductor pattern SP. A first insulating layer INS1 may be disposed on the semiconductor pattern SP. A gate G of the transistor TR may be disposed on the first insulating layer INS1. A second insulating layer INS2 may be disposed on the gate G. A third insulating layer INS3 may be disposed on the second insulating layer INS2.

A connection electrode CNE may include a first connection electrode CNE1 and a second connection electrode CNE2 to connect the transistor TR to the light emitting element OLED. The first connection electrode CNE1 may be disposed on the third insulating layer INS3 and may be connected to the drain D via a first contact hole CH1 defined through the first, second, and third insulating layers INS1, INS2, and INS3.

A fourth insulating layer INS4 may be disposed on the first connection electrode CNE1. A fifth insulating layer INS5 may be disposed on the fourth insulating layer INS4. The second connection electrode CNE2 may be disposed on the fifth insulating layer INS5. The second connection electrode CNE2 may be connected to the first connection electrode CNE1 via a second contact hole CH2 defined through the fourth insulating layer INS4 and the fifth insulating layer INS5.

A sixth insulating layer INS6 may be disposed on the second connection electrode CNE2. Each of the first to sixth insulating layers INS1 to INS6 may be an inorganic layer or an organic layer.

The first electrode AE may be disposed on the sixth insulating layer INS6. The first electrode AE may be connected to the second connection electrode CNE2 via a third contact hole CH3 defined through the sixth insulating layer INS6. A pixel definition layer PDL may be disposed on the first electrode AE and the sixth insulating layer INS6. The pixel definition layer PDL may be provided with an opening PX_OP defined therethrough to expose a predetermined portion of the first electrode AE.

The hole control layer HCL may be disposed on the first electrode AE and the pixel definition layer PDL. The hole control layer HCL may include a hole transport layer and a hole injection layer.

The light emitting layer EML may be disposed on the hole control layer HCL. The light emitting layer EML may be disposed in an area corresponding to the opening PX_OP. The light emitting layer EML may include an organic material and/or an inorganic material. The light emitting layer EML may generate a light having one of red, green, and blue colors.

The electron control layer ECL may be disposed on the light emitting layer EML and the hole control layer HCL. The electron control layer ECL may include an electron transport layer and an electron injection layer. The second electrode CE may be disposed on the electron control layer ECL.

A thin film encapsulation layer TFE may be disposed on the second electrode CE to cover the pixel PX. The thin film encapsulation layer TFE may include a first encapsulation layer EN1 disposed on the second electrode CE, a second encapsulation layer EN2 disposed on the first encapsulation layer EN1, and a third encapsulation layer EN3 disposed on the second encapsulation layer EN2.

The first and third encapsulation layers EN1 and EN3 may include an inorganic insulating layer and may protect the pixel PX from moisture and oxygen. The second encapsulation layer EN2 may include an organic insulating layer and may protect the pixel PX from a foreign substance such as dust particles.

A first voltage may be applied to the first electrode AE via the transistor TR, and a second voltage having a voltage level lower than that of the first voltage may be applied to the second electrode CE. Holes and electrons injected into the light emitting layer EML may be recombined to generate excitons, and the light emitting element OLED may emit the light by the excitons that return to a ground state from an excited state.

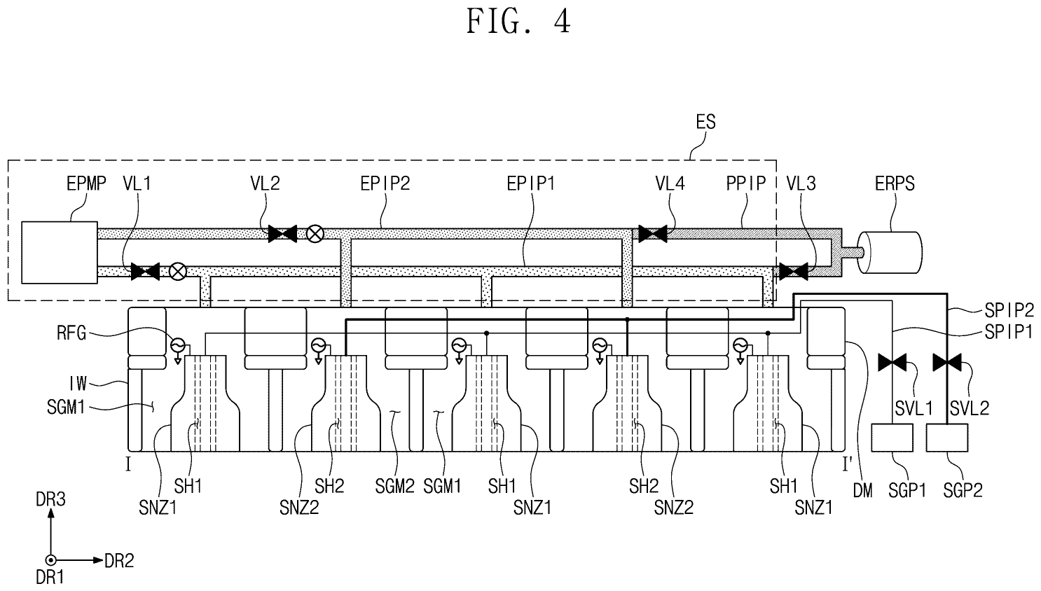

FIG. 4 is a cross-sectional view taken along line I-I′ shown in FIG. 1.

FIG. 4 shows a cross-section of the deposition module DM taken along the line I-I′ parallel to the second direction DR2

As an example, components of the atomic layer deposition apparatus ADD connected to the deposition module DM are illustrated along with the deposition module DM.

Referring to FIG. 4, the atomic layer deposition apparatus ADD may include the deposition module DM, first and second source gas supply parts SGP1 and SGP2, first and second source gas valves SVL1 and SVL2, valves VL1 to VL4, an exhaust part ES, an exhaust plasma supply part ERPS, and an exhaust plasma pipe PPIP.

The deposition module DM may include first and second source gas supply modules SGM1 and SGM2 and a barrier wall IW. The first and second source gas supply modules SGM1 and SGM2 and the barrier wall IW may be accommodated in a case (not shown).

In an embodiment, a lower portion of the case may be opened, and thus, lower portions of the first and second source gas supply modules SGM1 and SGM2 may be exposed to the outside.

The first and second source gas supply modules SGM1 and SGM2 may spray different source gases to the substrate (not shown) below the deposition module DM. The first and second source gas supply modules SGM1 and SGM2 may be connected to the first and second source gas supply parts SGP1 and SGP2 that supply the source gases.

The first and second source gas supply parts SGP1 and SGP2 may be connected to first and second source gas nozzles SNZ1 and SNZ2 through the valves SVL1 and SVL2, respectively.

The first source gas valve SVL1 may be connected to the first source gas supply part SGP1 and the first source gas nozzles SNZ1. The first source gas valve SVL1 may be connected to the first source gas nozzles SNZ1 through a pipe. The first source gas valve SVL1 may be opened and closed to control the supply of the first source gas to the first source gas nozzles SNZ1.

The second source gas valve SVL2 may be connected to the second source gas supply part SGP2 and the second source gas nozzles SNZ2. The second source gas valve SVL2 may be connected to the second source gas nozzles SNZ2 through a pipe. The second source gas valve SVL2 may be opened and closed to control the supply of the second source gas to the second source gas nozzles SNZ2.

The first and second source gas supply modules SGM1 and SGM2 may be connected to a radio frequency (“RF”) generator RFG. The RF generator RFG may generate an RF plasma by applying the RF energy to a gas. The RF generator RFG may apply the RF plasma to the first and second source gas supply modules SGM1 and SGM2. The first and second source gas supply modules SGM1 and SGM2 may improve a reactivity of the source gas using the RF plasma.

The first source gas supply module SGM1 may be connected to the first source gas supply part SGP1. The first source gas supply module SGM1 may supply the first source gas to the substrate (not shown) below the deposition module DM. The first source gas may be defined as the above-described precursor PCS. As an example, the atomic layer deposition apparatus ADD may deposit silicon oxide (SiO₂) of the oxide semiconductor on the substrate (not shown) below the deposition module DM. In this case, the first source gas may include silane (SiH₄).

The first source gas supply module SGM1 may include the first source gas nozzles SNZ1 connected to the first source gas supply part SGP1. The first source gas nozzles SNZ1 may be arranged in the second direction DR2. Each of the first source gas nozzles SNZ1 may be provided with a plurality of first source gas spray holes SH1 defined therethrough. The first source gas module SGM1 may spray the first source gas through the first source gas spray hole SH1.

The second source gas supply module SGM2 may be connected to the second source gas supply part SGP2. The second source gas supply module SGM2 may supply the second source gas to the substrate (not shown) below the deposition module DM. The second source gas supply module SGM2 may be spaced apart from the first source gas supply module SGM1 in the second direction DR2.

The second source gas may be defined as the reactant RCT. In this case, the second source gas may include O₂ or N₂O. The second source gas may be decomposed by the plasma P and may be supplied as the radicals onto the substrate SUB.

The second source gas supply module SGM2 may include the second source gas nozzles SNZ2 connected to the second source gas supply part SGP2. The second source gas nozzles SNZ2 may be arranged in the second direction DR2. Each of the second source gas nozzles SNZ2 may be provided with a plurality of second source gas spray holes SH2. The second source gas module SGM2 may spray the second source gas through the second source gas spray hole SH2

The first and second source gas supply modules SGM1 and SGM2 may be divided into multiple areas in the second direction DR2, and the first and second source gas nozzles SNZ1 and SNZ2 may be defined in the divided multiple areas. The first source gas supply modules SGM1 may be divided by the source gas nozzles SNZ1, and the second source gas supply modules SGM2 may be divided by the source gas nozzles SNZ2. The first and second source gas nozzles SNZ1 and SNZ2 may be repeatedly and alternately arranged in the order of the first source gas nozzle SNZ1 and the second source gas nozzle SNZ2.

The exhaust part ES may include an exhaust pump EPMP, a first exhaust pipe EPIP1, a second exhaust pipe EPIP2 and the valves VL1 and VL2. The exhaust part ES may be connected to the first and second source gas supply modules SGM1 and SGM2. The exhaust part ES may be connected to the first and second exhaust pipes EPIP1 and EPIP2 and the first and second source gas supply modules SGM1 and SGM2.

The exhaust pump EPMP may apply an exhaust pressure (e.g., low pressure) to the first and second exhaust pipes EPIP1 and EPIP2. The exhaust pump EPMP may be connected to the first and second exhaust pipes EPIP1 and EPIP2. The exhaust pump EPMP may be connected to the first and second source gas supply modules SGM1 and SGM2 via the first and second exhaust pipes EPIP1 and EPIP2 and the valves VL1 and VL2. A first valve VL1 may connect the exhaust pump EPMP to the first exhaust pipe EPIP1. A second valve VL2 may connect the exhaust pump EPMP to the second exhaust pipe EPIP2.

The exhaust pump EPMP may be connected to the first and second exhaust pipes EPIP1 and EPIP2 by the first and second valves VL1 and VL2, respectively, and may apply the exhaust pressure to the first and second source gas supply modules SGM1 and SGM2. The first valve VL1 may be opened and closed to control the application of the exhaust pressure to the first source gas supply module SGM1. The first valve VL1 may connect the exhaust pump EPMP to the first source gas supply module SGM1 and may control the exhaust of the exhaust plasma output from the first source gas supply module SGM1.

The second valve VL2 may be opened and closed to control the application of the exhaust pressure to the second source gas supply module SGM2. The second valve VL2 may connect the exhaust pump EPMP to the second exhaust pipe EPIP2 and may control the exhaust of the exhaust plasma output from the second source gas supply module SGM2. Due to the exhaust pressure (e.g., low pressure), gases remaining in the process chamber may be exhausted to the outside through the first and second exhaust pipes EPIP1 and EPIP2.

The exhaust plasma supply part ERPS may apply the exhaust plasma to the exhaust part ES. The exhaust plasma supply part ERPS may be connected to the exhaust part ES through the exhaust plasma pipe PPIP and the valves VL3 and VL4. The exhaust plasma pipe PPIP may be connected to the first and second exhaust pipes EPIP1 and EPIP2.

A third valve VL3 may be connected to the first exhaust pipe EPIP1. The third valve VL3 may connect the first exhaust pipe EPIP1 and the exhaust plasma pipe PPIP and may control the application of the exhaust plasma. The third valve VL3 may be opened and closed to control the application of the exhaust plasma to the first exhaust pipe EPIP1.

A fourth valve VL4 may be connected to the second exhaust pipe EPIP2. The fourth valve VL4 may be opened and closed to control the application of the exhaust plasma to the second exhaust pipe EPIP2. The fourth valve VL4 may connect the second exhaust pipe EPIP2 and the exhaust plasma pipe PPIP and may control the application of the exhaust plasma.

The exhaust plasma supply part ERPS may apply the exhaust plasma in a remote plasma method. The exhaust plasma supply part ERPS may be provided spaced apart from the process chamber (not shown) and may apply the exhaust plasma through the exhaust plasma pipe PPIP. The exhaust plasma supply part ERPS may apply the exhaust plasma to the exhaust plasma pipe PPIP.

As an example, the exhaust plasma supply part ERPS may generate and supply fluorine (F) radicals. The exhaust plasma may contain nitrogen trifluoride (NF₃). The exhaust plasma may be applied to the first and second exhaust pipes EPIP1 and EPIP2 to clean the deposited layer in the first and second exhaust pipes EPIP1 and EPIP2. The deposited layer in the first and second exhaust pipes EPIP1 and EPIP2 may be decomposed by the exhaust plasma, and silicon tetrafluoride (SiF₄) may be generated. The generated silicon tetrafluoride may be exhausted to the outside through the first and second exhaust pipes EPIP1 and EPIP2.

That is, the exhaust part ES may apply the exhaust plasma to the first and second source gas supply modules SGM1 and SGM2 and may suck and exhaust the exhaust plasma supplied to the first and second source gas supply modules SGM1 and SGM2.

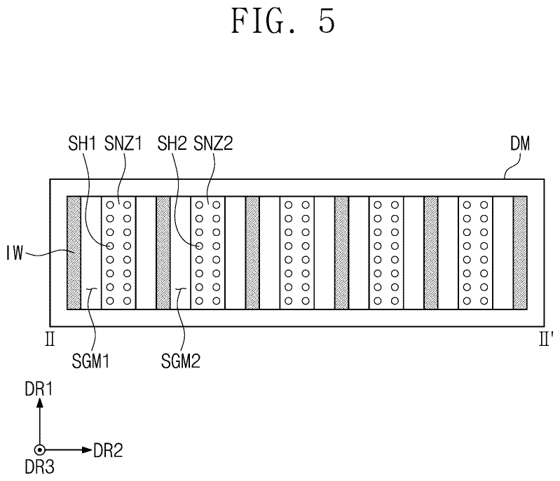

FIG. 5 is a cross-sectional view taken along line II-II′ shown in FIG. 1. FIG. 5 is a cross-sectional view of the first and second source gas supply modules SGM1 and SGM2 and the barrier wall IW.

Referring to FIG. 5, the deposition module DM may include the first and second source gas supply modules SGM1 and SGM2 and the barrier wall IW. The barrier wall IW may be provided in plural, and the barrier walls IW may be arranged between the first and second source gas nozzles SNZ1 and SNZ2.

The first and second source gas spray holes SH1 and SH2 may be defined through the first and second source gas nozzles SNZ1 and SNZ2, respectively. As an example, the first and second source gas spray holes SH1 and SH2 may be arranged in the first direction DR1 and the second direction DR2. As shown in FIG. 5, the first and second source gas spray holes SH1 and SH2 may be arranged in the first and second source gas nozzles SNZ1 and SNZ2 in a matrix form, however, the present disclosure should not be limited thereto or thereby.

The first and second source gas supply modules SGM1 and SGM2 and the barrier walls IW may extend longer in the first direction DR1 than the second direction DR2 to have a bar shape. Each barrier wall IW may be disposed between the first source gas supply module SGM1 and the second source gas supply module SGM2. The barrier wall IW may have a slit shape.

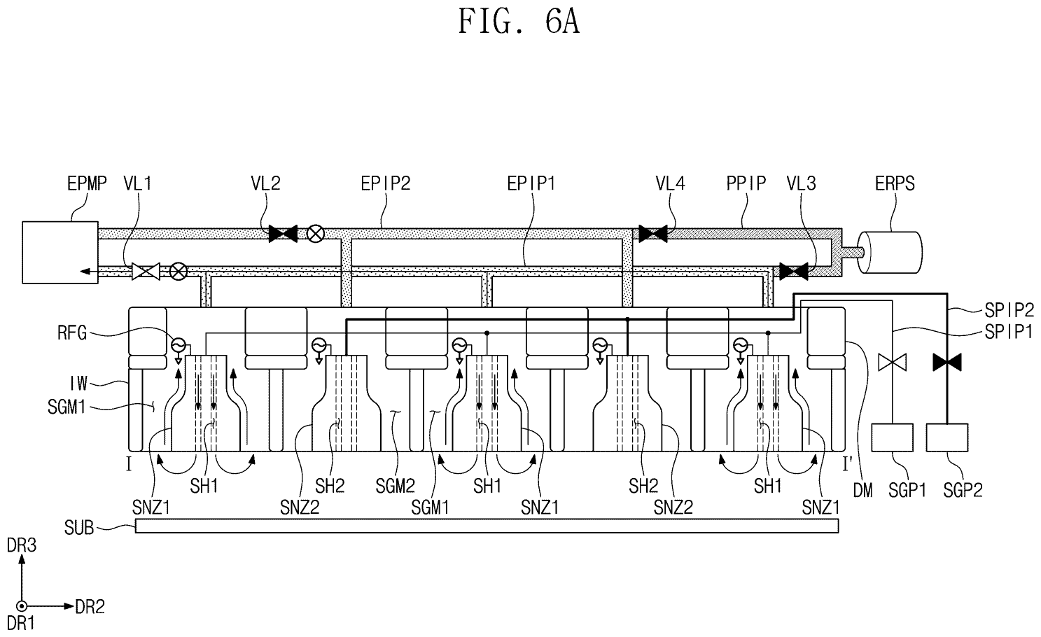

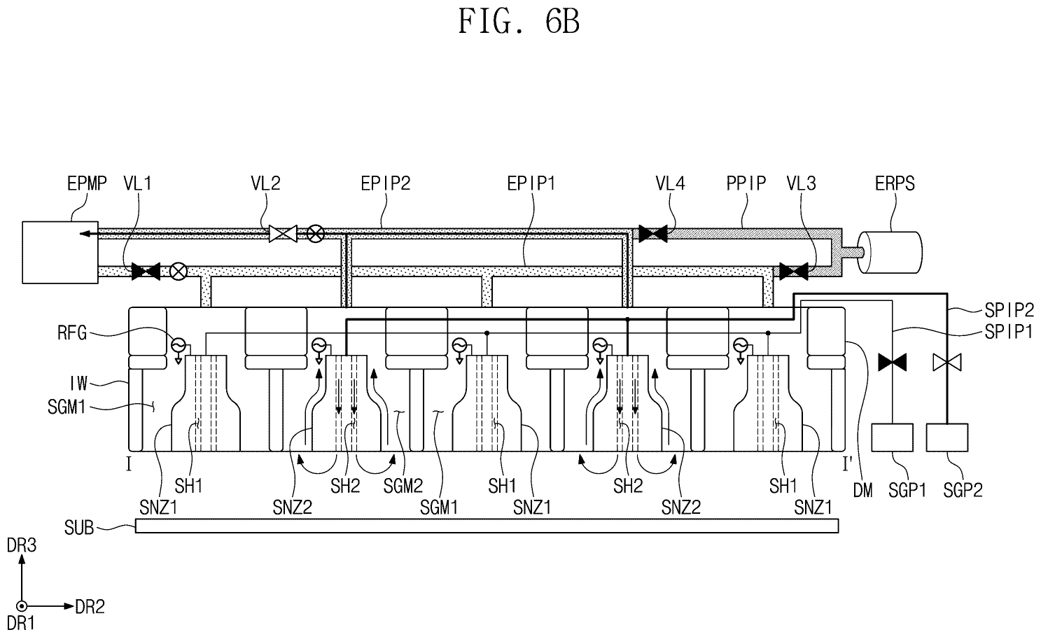

FIG. 6A is a view illustrating a process of supplying the first source gas to the substrate. FIG. 6B is a view illustrating a process of supplying the second source gas to the substrate. As an example, FIGS. 6A and 6B show a cross-section corresponding to the cross-section of FIG. 4.

Referring to FIG. 6A, the first source gas valve SVL1 may be opened, and the second source gas valve SVL2 may be closed. The first source gas supply part SGP1 may supply the first source gas to the first source gas supply module SGM1 through the opened first source gas valve SVL1.

The first source gas may be supplied to the first source gas nozzles SNZ1 through the first source gas valve SVL1 and a first source pipe SPIP1. The first source gas may be sprayed onto the substrate SUB through the first source gas nozzles SNZ1. Accordingly, the first source gas may be deposited on the substrate SUB.

After the first source gas is supplied to the upper surface of the substrate SUB, the supply of the first source gas may be stopped. When the supply of the first source gas is stopped, the first source gas valve SVL1 may be closed.

Even if the supply of the first source gas is stopped, residual first source gas may still remain in the first source gas supply module SGM1. The exhaust pump EPMP may apply the exhaust pressure to the first source gas supply module SGM1 to remove the first source gas remaining in the first source gas supply module SGM1.

The exhaust pump EPMP may apply the exhaust pressure to the first source gas supply module SGM1 through the first exhaust pipe EPIP1 and the first valve VL1. When the exhaust pump EPMP operates, the first valve VL1 may be opened, and the second, third, and fourth valves VL2, VL3, and VL4 may be closed. The exhaust pressure may be applied to the first source gas supply module SGM1 through the opened first valve VL1. The residual first source gas may be exhausted through the first exhaust pipe EPIP1 by the exhaust pressure (e.g., low pressure).

Referring to FIG. 6B, the second source gas valve SVL2 may be opened, and the first source gas valve SVL1 may be closed. The second source gas supply part SGP2 may supply the second source gas to the second source gas supply module SGM2 through the opened second source gas valve SVL2.

The second source gas may be supplied to the second source gas nozzles SNZ2 through the second source gas valve SVL2 and a second source pipe SPIP2. The second source gas may be sprayed onto the substrate SUB through the second source gas nozzles SNZ2. Accordingly, the second source gas may be deposited on the substrate SUB.

After the second source gas is supplied to the upper surface of the substrate SUB, the supply of the second source gas may be stopped. When the second source gas valve SVL2 is closed, the supply of the second source gas may be stopped.

Even if the supply of the second source gas is stopped, residual second source gas may still remain in the second source gas supply module SGM2. The exhaust pump EPMP may apply the exhaust pressure to the second source gas supply module SGM2 to remove the second source gas remaining in the second source gas supply module SGM2.

The exhaust pump EPMP may apply the exhaust pressure to the second source gas supply module SGM2 through the second exhaust pipe EPIP2 and the second valve VL2. When the second valve VL2 is opened, the exhaust pump EPMP may operate, and the first, third, and fourth valves VL1, VL3, and VL4 may be closed. The exhaust pressure may be applied to the second source gas supply module SGM2 through the opened second valve VL2. The residual second source gas may be exhausted through the second exhaust pipe EPIP2 by the exhaust pressure (e.g., low pressure).

In a case where the deposition module DM moves from a rightmost position of the substrate SUB to a leftmost position of the substrate SUB, the first source gas may be first provided on the substrate SUB, and then the second source gas may be sequentially provided on the substrate SUB. As the first source gas is deposited on the substrate SUB and then the second source gas is deposited on the substrate SUB, the atomic layer, for example, silicon oxide (SiO₂), may be formed on the substrate SUB.

The above-described processes may be repeatedly performed to form the atomic layer with a desired thickness. As an example, due to the reciprocal movement of the deposition module DM in the first direction DR1 and the direction opposite to the first direction DR1, the atomic layer may be repeatedly deposited on the substrate SUB.

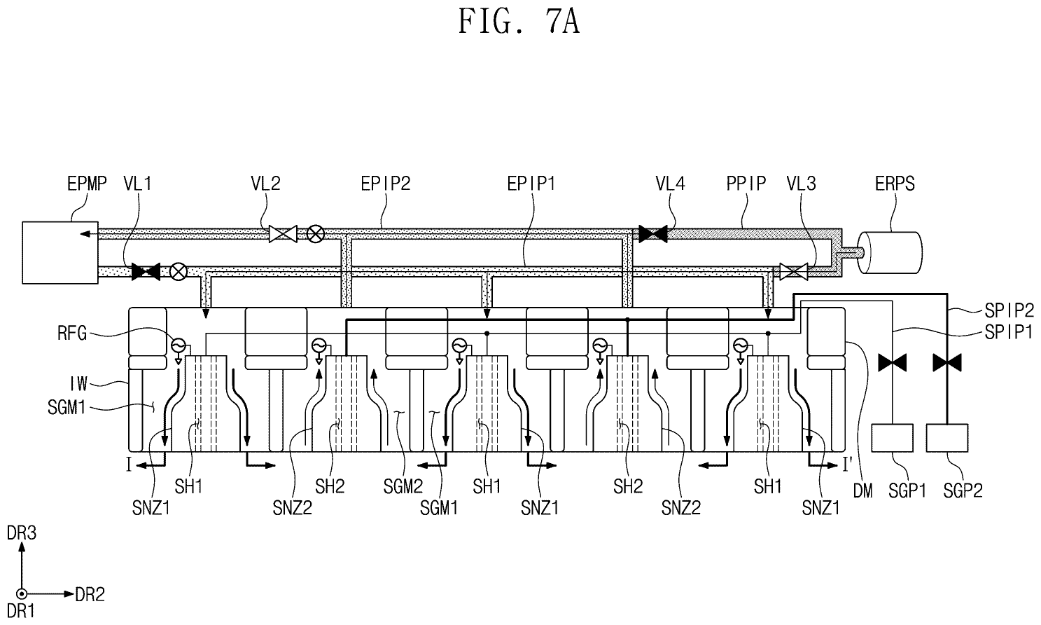

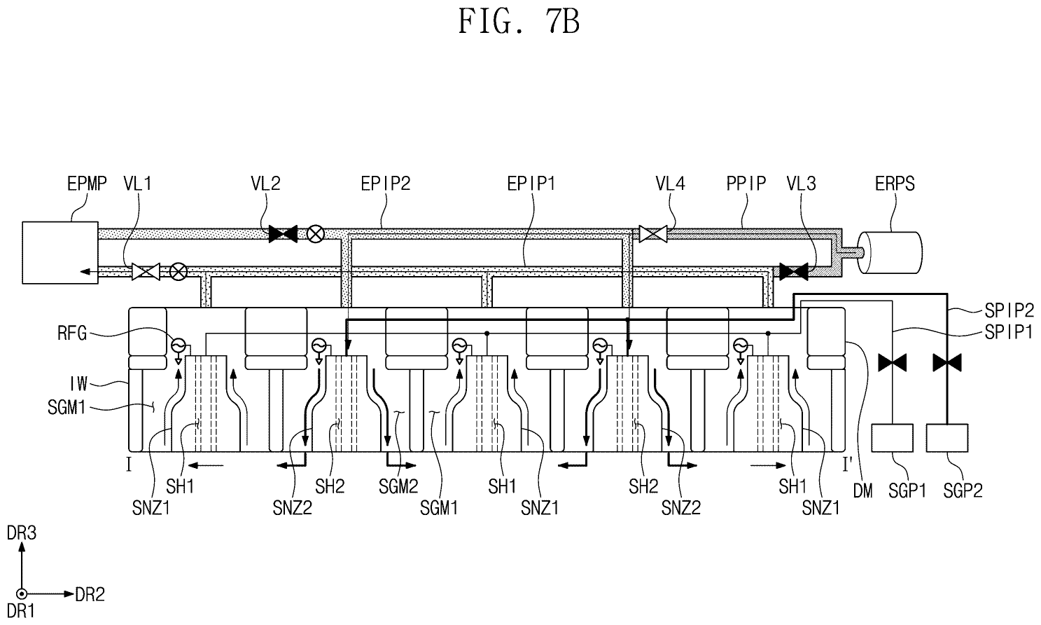

FIGS. 7A and 7B are views illustrating an operation of the exhaust plasma supply part ERPS after the atomic layer is formed on the substrate according to an embodiment of the present disclosure. As an example, FIGS. 7A and 7B show a cross-section corresponding to the cross-section of FIG. 4. In FIG. 7B, operations that are different from those described with reference to FIG. 7A will be mainly described.

Referring to FIG. 7A, when the third valve VL3 is opened, the exhaust plasma is applied to the first exhaust pipe EPIP1, and the fourth valve VL4 may be closed. The exhaust plasma supply part ERPS may apply the exhaust plasma to the first exhaust pipe EPIP1 through the third valve VL3 and the exhaust plasma pipe PPIP. The exhaust plasma may react with a layer of deposits on the inner wall of the first exhaust pipe EPIP1 and may remove the layer of deposits. The exhaust plasma may be applied to the first source gas supply module SGM1 through the first exhaust pipe EPIP1.

As an example, the exhaust plasma may contain the fluorine (F) radicals. The exhaust plasma may contain the nitrogen trifluoride (NF₃). The layer of deposits in the first exhaust pipe EPIP1 may be decomposed by the fluorine (F) radicals. The layer of deposits in the first exhaust pipe EPIP1 may be decomposed into the silicon tetrafluoride (SiF₄) by the fluorine (F) radicals.

The first exhaust pipe EPIP1 may receive the exhaust plasma and may apply the exhaust plasma to the first source gas supply module SGM1, and the exhaust plasma applied to the first source gas supply module SGM1 may be exhausted to the second exhaust pipe EPIP2 through the second source gas supply module SGM2. When the second valve VL2 is opened, the exhaust plasma may be exhausted through the second exhaust pipe EPIP2, and the first valve VL1 may be closed.

In detail, the layer of deposits in the first exhaust pipe EPIP1 may be cleaned and exhausted by the exhaust pump EPMP. The exhaust pump EPMP may apply the exhaust pressure to the second source gas supply module SGM2 through the second valve VL2 and the second exhaust pipe EPIP2. The cleaned layer of deposits in the first exhaust pipe EPIP1 may be exhausted through the second source gas supply module SGM2.

That is, the cleaned layer of deposits in the first exhaust pipe EPIP1 may move downward from an upper side to a lower side of the first source gas supply module SGM1, may move upward from a lower side to an upper side of the second source gas supply module SGM2 by the exhaust pressure (e.g., low pressure), and then may be exhausted to the outside through the second exhaust pipe EPIP2. Accordingly, since the exhaust plasma supply part ERPS applies the generated exhaust plasma direct to the first exhaust pipe EPIP1, the first exhaust pipe EPIP1 may be cleaned more efficiently.

In addition, a portion of the exhaust plasma may be applied to a lower portion of the first source gas supply module SGM1 and may remove deposits generated in areas rather than the substrate (not shown) below the deposition module DM.

Referring to FIG. 7B, when the fourth valve VL4 is opened, the exhaust plasma may be applied to the second exhaust pipe EPIP2, and the third valve VL3 may be closed. When the first valve VL1 is opened, the exhaust plasma may be exhausted through the first exhaust pipe EPIP1, and the second valve VL2 may be closed.

The second exhaust pipe EPIP2 may receive the exhaust plasma and may apply the exhaust plasma to the second source gas supply module SGM2.

The exhaust plasma supply part ERPS may apply the exhaust plasma to the second exhaust pipe EPIP2 through the fourth valve VL and the exhaust plasma pipe PPIP. The exhaust plasma may react with a layer of deposits on the inner wall of the second exhaust pipe EPIP2 and may remove the layer of deposits. In the present embodiment, the cleaning process of the first exhaust pipe EPIP1 is performed first, but it should not be limited thereto or thereby, and the cleaning process of the second exhaust pipe EPIP2 may be performed first.

The layer of deposits of the second exhaust pipe EPIP2 may be exhausted by the exhaust pump EPMP after being cleaned. The exhaust pump EPMP may apply the exhaust pressure (e.g., low pressure) to the first source gas supply module SGM1 through the first valve VL1 and the first exhaust pipe EPIP1. The cleaned layer of deposits in the second exhaust pipe EPIP2 may be exhausted through the first source gas supply module SGM1.

That is, the cleaned layer of deposits in the second exhaust pipe EPIP2 may move downward from the upper side to the lower side of the second source gas supply module SGM2, may move from the lower side to the upper side of the first source gas supply module SGM1 by the exhaust pressure, and then may be exhausted through the first exhaust pipe EPIP1.

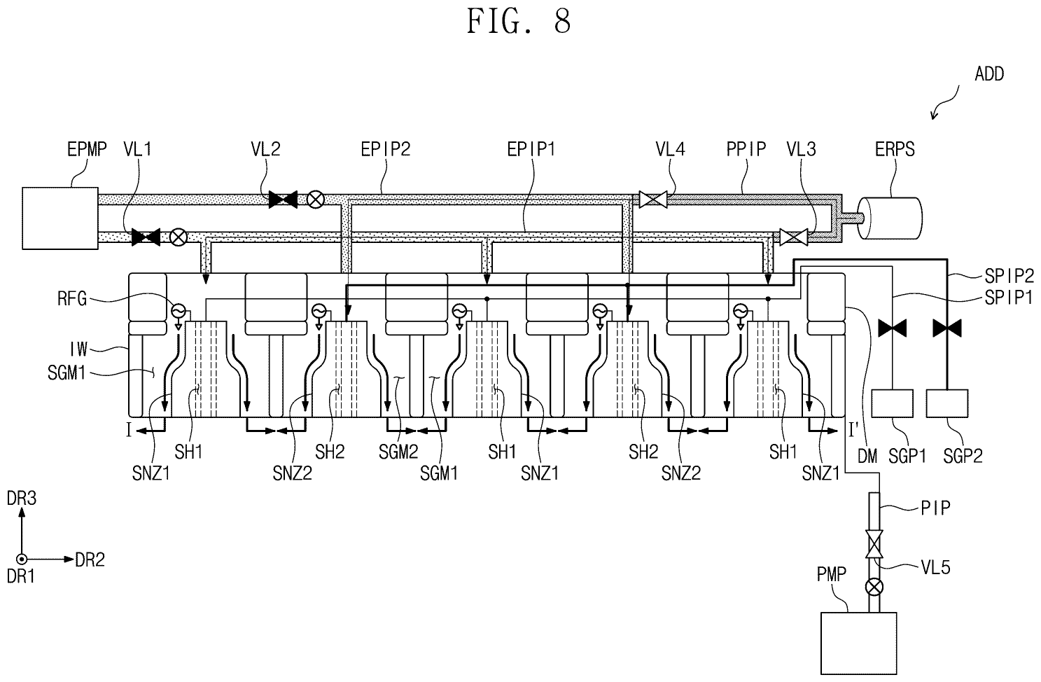

FIG. 8 is a view illustrating an operation of an exhaust plasma supply part ERPS after an atomic layer is formed on a substrate according to an embodiment of the present disclosure.

Referring to FIG. 8, an atomic layer deposition apparatus ADD may include a pipe PIP connected to first and second source gas supply modules SGM1 and SGM2, a pump PMP connected to the pipe PIP, and a fifth valve VL5 connecting the pipe PIP and the pump PMP and controlling the exhaust of an exhaust plasma.

When a third valve VL3 and a fourth valve VL4 are opened, the exhaust plasma may be applied to first and second exhaust pipes EPIP1 and EPIP2, and a first valve VL1 and a second valve VL2 may be closed. The exhaust plasma supply part ERPS may apply the exhaust plasma to the first and second exhaust pipes EPIP1 and EPIP2 through the third and fourth valves VL3 and VL4 and an exhaust plasma pipe PPIP. The exhaust plasma may react with a layer of deposits on an inner wall of the first and second exhaust pipes EPIP1 and EPIP2 and may remove the layer of deposits.

The exhaust plasma may be applied to the first and second source gas supply modules SGM1 and SGM2 through the first and second exhaust pipes EPIP1 and EPIP2, respectively. The layer of deposits in the first and second exhaust pipes EPIP1 and EPIP2 may be decomposed by fluorine (F) radicals.

The layer of deposits in the first and second exhaust pipes EPIP1 and EPIP2 may be exhausted by the pump PMP after being cleaned. The pump PMP may apply an exhaust pressure to the first and second source gas supply modules SGM1 and SGM2 through the fifth valve VL5 and the pipe PIP. When the fifth valve VL5 is opened, the exhaust plasma may be exhausted to the pump PMP.

The cleaned layer of deposits in the first and second exhaust pipes EPIP1 and EPIP2 may be exhausted through the first and second source gas supply modules SGM1 and SGM2, respectively. The exhaust plasma applied to the first and second source gas supply modules SGM1 and SGM2 may be exhausted through the pipe PIP.

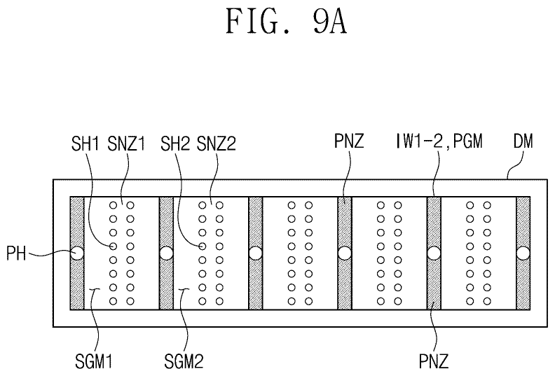

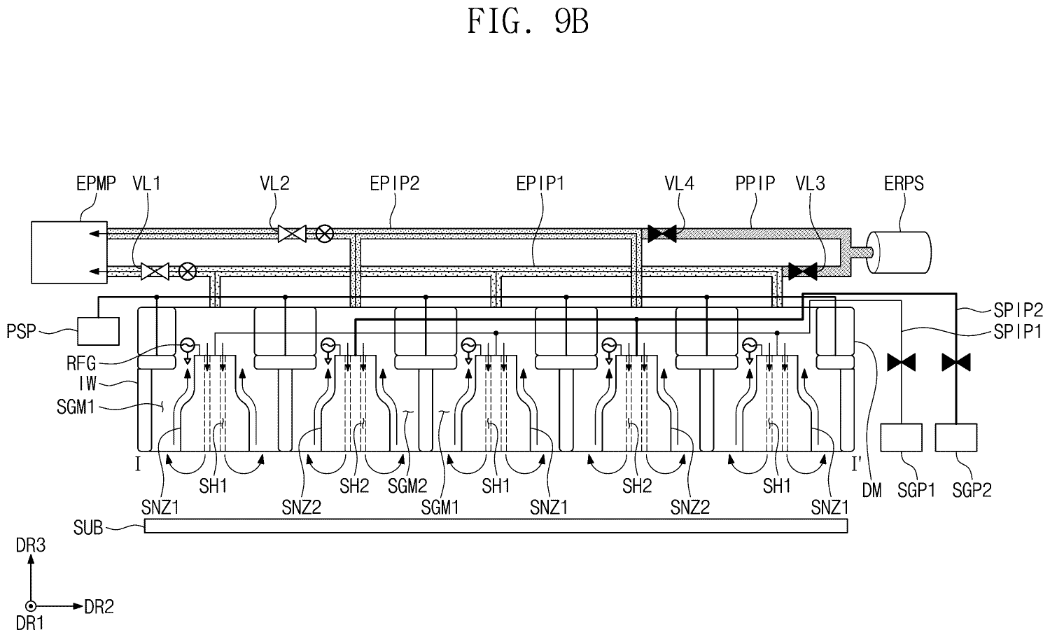

FIG. 9A is a cross-sectional view of a deposition module according to an embodiment of the present disclosure. As an example, FIG. 9A shows a cross-section corresponding to the cross-section of FIG. 5. In FIG. 9A, components that are different from those described with reference to FIG. 5 will be mainly described.

Referring to FIG. 9A, a purge gas supply module PGM may be disposed between a first source gas supply module SGM1 and a second source gas supply module SGM2. As an example, a barrier wall IW1-2 may be defined as the purge gas supply module PGM. The purge gas supply module PGM may have a slit shape.

The purge gas supply module PGM may include a purge gas nozzle PNZ connected to a purge gas supply part PSP (refer to FIG. 9B). The purge gas nozzle PNZ may be provided with a purge gas spray hole PH defined therethrough. The purge gas supply module PGM may spray a purge gas through the purge gas spray hole PH. FIG. 9A shows one purge gas spray hole PH defined through the purge gas nozzle PNZ as a representative example, however, the number of the purge gas spray holes PH should not be limited thereto or thereby. For instance, the purge gas spray holes PH may be provided in plural.

First and second source gas nozzles SNZ1-2 and SNZ2-2 and the purge gas nozzle PNZ may be repeatedly arranged in the order of the first source gas nozzle SNZ1-2, the second source gas nozzle SNZ2-2, and the purge gas nozzle PNZ.

An exhaust part ES (refer to FIG. 4) may be connected to the first and second source gas supply modules SGM1 and SGM2 and may be disposed above the first and second source modules SGM1 and SGM2 and the purge gas supply module PGM.

FIG. 9B is a cross-sectional view of an atomic layer deposition apparatus according to an embodiment of the present disclosure. As an example, FIG. 9B shows a cross-section corresponding to the cross-section of FIG. 4.

Referring to FIG. 9B, the purge gas supply part PSP may supply a purge gas to a purge gas supply module PGM. The purge gas supply module PGM may be connected to the purge gas supply part PSP through a purge gas pipe PPIP and may receive the purge gas. As an example, the purge gas may be an inert gas and may include one or more gases of argon (Ar), nitrogen (N₂), and helium (He), or a mixture of two or more gases of argon (Ar), nitrogen (N₂), and helium (He).

The purge gas supply part PSP may be connected to purge gas nozzles PNZ through the purge gas pipe PPIP. The purge gas supply part PSP may supply the purge gas to the purge gas nozzle PNZ through the purge gas pipe PPIP.

The purge gas nozzle PNZ may supply the purge gas to a substrate SUB through a purge gas spray hole PH. The purge gas may allow first and second source gases to be sprayed to a lower portion of first and second source gas supply modules SGM1 and SGM2 and may allow the first and second source gases not to be diffused to the other portions like an air curtain.

In addition, the purge gas may spatially divide the area into which the first source gas and the second source gas are injected. The first source gas and the second source gas may be sprayed in a limited deposition area by the purge gas.

An exhaust pump EPMP may apply an exhaust pressure to first and second exhaust pipes EPIP1 and EPIP2. The purge gas may be exhausted through the first and second exhaust pipes EPIP1 and EPIP2 by a residual first source gas, a residual second source gas, and the exhaust pressure.

Although the embodiments of the present disclosure have been described, it is understood that the present disclosure should not be limited to these embodiments but various changes and modifications can be made by one ordinary skilled in the art within the spirit and scope of the present disclosure as hereinafter claimed. Therefore, the disclosed subject matter should not be limited to any single embodiment described herein, and the scope of the present invention shall be determined according to the attached claims.

What is claimed is:

1. An atomic layer deposition apparatus comprising:
a source gas supply part, which supplies a plurality of source gases;
a source gas supply module connected to the source gas supply part;
an exhaust part connected to and disposed above the source gas supply module; and
an exhaust plasma supply part connected to the exhaust part and which applies an exhaust plasma to the exhaust part,
wherein the exhaust part is configured to apply the exhaust plasma received from the exhaust plasma supply part to the source gas supply module, suck the exhaust plasma applied to the source gas supply module, and exhausts the sucked plasma to an outside.

2. The atomic layer deposition apparatus of claim 1, wherein the source gas supply module comprises:
a first source gas supply module configured to supplies a first source gas to a substrate; and
a second source gas supply module configured to supplies a second source gas to the substrate,
wherein the plurality of source gases includes the first source gas and the second source gas.

3. The atomic layer deposition apparatus of claim 2, wherein the first source gas supply module comprises a plurality of first source gas nozzles connected to the source gas supply part, and the second source gas supply module comprises a plurality of second source gas nozzles connected to the source gas supply part.

4. The atomic layer deposition apparatus of claim 3, wherein the first and second source gas nozzles are alternately arranged.

5. The atomic layer deposition apparatus of claim 4, further comprising a plurality of barrier walls disposed between the first and second source gas nozzles.

6. The atomic layer deposition apparatus of claim 2, wherein the exhaust part comprises:
an exhaust pump;
a first exhaust pipe connected to the first source gas supply module; and
a second exhaust pipe connected to the second source gas supply module.

7. The atomic layer deposition apparatus of claim 6, further comprising an exhaust plasma pipe connected to the first and second exhaust pipes,
wherein the exhaust plasma supply part applies the exhaust plasma to the exhaust plasma pipe.

8. The atomic layer deposition apparatus of claim 7, further comprising:
a first valve configured to connect the first exhaust pipe and the exhaust pump and control an exhaust of the exhaust plasma sucked from the first source gas supply module to the outside; and
a second valve configured to connect the second exhaust pipe and the exhaust pump and control the exhaust of the exhaust plasma sucked from the second source gas supply module to the outside.

9. The atomic layer deposition apparatus of claim 8, further comprising:
a third valve configured to connect the first exhaust pipe and the exhaust plasma pipe and control an application of the exhaust plasma to the first exhaust pipe; and
a fourth valve configured to connect the second exhaust pipe and the exhaust plasma pipe and control the application of the exhaust plasma to the second exhaust pipe.

10. The atomic layer deposition apparatus of claim 9, wherein the first exhaust pipe receives the exhaust plasma from the exhaust plasma supply part and applies the exhaust plasma to the first source gas supply module, and the exhaust plasma applied to the first source gas supply module is exhausted to the second exhaust pipe through the second source gas supply module.

11. The atomic layer deposition apparatus of claim 10, wherein, when the third valve is opened, the exhaust plasma is applied from the exhaust plasma supply part to the first exhaust pipe and the fourth valve is closed, and when the second valve is opened, the exhaust plasma sucked from the second source gas supply module is exhausted to the second exhaust pipe and the first valve is closed.

12. The atomic layer deposition apparatus of claim 9, wherein the second exhaust pipe receives the exhaust plasma from the exhaust plasma supply part and applies the exhaust plasma to the second source gas supply module, and the exhaust plasma applied to the second source gas supply module is exhausted to the first exhaust pipe through the first source gas supply module.

13. The atomic layer deposition apparatus of claim 2, wherein, when the fourth valve is opened, the exhaust plasma is applied from the exhaust plasma supply part to the second exhaust pipe and the third valve is closed, and when the first valve is opened, the exhaust plasma sucked from the first source gas supply module is exhausted to the first exhaust pipe and the second valve is closed.

14. The atomic layer deposition apparatus of claim 9, further comprising:
a pipe connected to the first and second source gas supply modules;
a pump connected to the pipe; and
a fifth valve configured to connect the pipe and the pump and control the exhaust of the exhaust plasma to the pump.

15. The atomic layer deposition apparatus of claim 14, wherein the first exhaust pipe receives the exhaust plasma and applies the exhaust plasma to the first source gas supply module, the second exhaust pipe receives the exhaust plasma and applies the exhaust plasma to the second source gas supply module, and the exhaust plasma applied to the first and second source gas supply modules are exhausted through the pipe.

16. The atomic layer deposition apparatus of claim 15, wherein, when the third and fourth valves are opened, the exhaust plasma is applied to the first and second exhaust pipes and the first and second valves are closed, and when the fifth valve is opened, the exhaust plasma is exhausted to the pump.

17. An atomic layer deposition apparatus comprising:
a source gas supply part, which supplies a plurality of source gases including a first source gas and a second source gas;
a first source gas supply module connected to the source gas supply part and which supplies the first source gas;
a second source gas supply module connected to the source gas supply part and which supplies the second source gas;
a purge gas supply module disposed between the first source gas supply module and the second source gas supply module;
a purge gas supply part, which supplies a purge gas to the purge gas supply module;
an exhaust part connected to the first and second source gas supply modules and disposed above the first and second source gas supply modules and the purge gas supply module; and
an exhaust plasma supply part connected to the exhaust part and which applies an exhaust plasma to the exhaust part,
wherein the exhaust part is configured to apply the exhaust plasma received from the exhaust plasma supply part to the first and second source gas supply modules, and
the first and second source gas supply modules exhaust the exhaust plasma applied thereto to the exhaust part.

18. The atomic layer deposition apparatus of claim 17, wherein the purge gas supply module has a slit shape.

19. The atomic layer deposition apparatus of claim 17, wherein the first source gas supply module comprises a first source gas nozzle connected to the source gas supply part, the second source gas supply module comprises a second source gas nozzle connected to the source gas supply part, and the purge gas supply module comprises a purge gas nozzle connected to the purge gas supply part.

20. The atomic layer deposition apparatus of claim 19, wherein the first and second source gas nozzles and the purge gas nozzle are repeatedly arranged in an order of the first source gas nozzle, the second source gas nozzle, and the purge gas nozzle.
